(19) United States
(12) Patent Application Publication
(10) Pub. No.: US 2025/0343066 A1
(43) Pub. Date: Nov. 6, 2025

(54) LIFT PIN ACTUATORS, ACTUATOR ARRANGEMENTS AND SEMICONDUCTOR PROCESSING SYSTEMS HAVING LIFT PIN ACTUATORS, AND METHODS OF MAKING LIFT PIN ACTUATORS AND ACTUATOR ARRANGEMENTS

(71) Applicant: ASM IP Holding B.V., Almere (NL)

(72) Inventor: Bradley Wayne Evans, Apache Junction, AZ (US)

(21) Appl. No.: 19/195,455

(22) Filed: Apr. 30, 2025

Related U.S. Application Data
(60) Provisional application No. 63/641,312, filed on May 1, 2024.

(51) Int. Cl. H01L 21/687; H01L 21/67

(52) U.S. Cl. CPC H01L 21/68742; H01L 21/67109; H01L 21/68764; H01L 21/68785

(57) ABSTRACT

A lift pin actuator includes an actuator body having a hub portion, a first arm portion and second arm portion, and a pad portion. The actuator body is arranged along a rotation axis, the hub portion extends about the rotation axis, and the arm portions extend outward from the hub portion in a direction opposite the rotation axis and parallel to one another. The pad portion is radially separated from the hub portion by the arm portions, the pad portion coupling the first arm portion to the second arm portion, and the pad portion has an engagement surface orthogonal relative to the rotation axis and coplanar with the arm portions to drive a lift pin above the engagement surface along the rotation axis. Chamber arrangements and semiconductor processing systems having lift pin actuators, as well as related methods of making lift pin actuators and actuator arrangements, are also described.

### CROSS-REFERENCE TO RELATED APPLICATIONS

This application claims priority to and the benefits of U.S. Provisional Patent Application Ser. No. 63/641,312, filed May 1, 2024, titled LIFT PIN ACTUATORS, ACTUATOR ARRANGEMENTS AND SEMICONDUCTOR PROCESSING SYSTEMS HAVING LIFT PIN ACTUATORS, AND METHODS OF MAKING LIFT PIN ACTUATORS AND ACTUATOR ARRANGEMENTS, the contents of which is incorporated herein by reference in its entirety.

### FIELD OF INVENTION

The present disclosure generally relates to material handling, and more particularly, to substrate handing such as semiconductor processing systems employed to deposit material layers onto substates and/or remove material from substrates.

### BACKGROUND OF THE DISCLOSURE

Mechanical systems commonly employ actuators, such as mechanical actuators, to displace and/or or move actuated components of the mechanical system. Mechanical actuators generally execute movement by converting one kind of motion, such as rotary motion, into another kind of motion, such as linear motion. The operation of such mechanical actuators is typically based on features of components incorporated in the mechanical system to effect actuation. Features of the components included in the mechanical system may be selected based on various requirements of the actuated component, for example the material forming various components of the mechanical system as well as the mechanical tolerances and tolerance stack-up of components within the mechanical system. In some mechanical systems, mechanical tolerances and/or tolerance stack-up may require that actuator components may be larger than otherwise desirable within the actuator assembly.

Such systems and methods have generally been acceptable for their intended purpose. However, there remains a need for improved lift pin actuators, actuator arrangements semiconductor processing systems including lift pin actuators, and methods of making lift pin actuators and actuator arrangements. The present disclosure provides a solution to this need.

### SUMMARY OF THE DISCLOSURE

A lift pin actuator is provided. The lift pin actuator includes an actuator body arranged along a rotation axis having a hub portion extending about the rotation axis; a first arm portion and a second arm portion extending outward from the hub portion and in a direction opposite the rotation axis, the second arm portion parallel to the first arm portion; a pad portion radially separated from the hub portion by the first arm portion and the second arm portion, the pad portion coupling the first arm portion to the second arm portion; wherein the pad portion has an engagement surface that is orthogonal relative to the rotation axis and coplanar with the first arm portion and the second arm portion of the actuator body to drive a lift pin above the engagement surface of the pad portion of the actuator body along the rotation axis.

In addition to one or more of the features described above, or as an alternative, further examples of the lift pin actuator may include that the pad portion is one of three (3) pad portions distributed circumferentially about the hub portion of the actuator body.

In addition to one or more of the features described above, or as an alternative, further examples of the lift pin actuator may include that the first arm portion and the second arm portion form a first arm pair of the actuator body, and wherein the actuator body has three (3) arm pairs distributed circumferentially about the hub portion of the actuator body.

In addition to one or more of the features described above, or as an alternative, further examples of the lift pin actuator may include that the actuator body is formed from a ceramic material, and wherein the actuator body is monolithically formed from a singular ceramic workpiece using a subtractive manufacturing technique.

In addition to one or more of the features described above, or as an alternative, further examples of the lift pin actuator may include that the hub portion of the actuator has an upper surface defining an upper surface aperture therein, a lower surface defining a seating aperture therein, and an interior surface coupling the upper surface aperture to the seating aperture.

In addition to one or more of the features described above, or as an alternative, further examples of the lift pin actuator may include that the interior surface of the hub portion defines a plurality of planar faces distributed circumferentially about the rotation axis.

In addition to one or more of the features described above, or as an alternative, further examples of the lift pin actuator may include that the plurality of planar faces are angled relative to at least one of the upper surface and the lower surface at a planar surface angle that is between about 5 degrees and about 45 degrees, or between about 5 degrees and about 30 degrees, or between about 5 degrees about 15 degrees, or even between about 5 degrees and about 10 degrees.

In addition to one or more of the features described above, or as an alternative, further examples of the lift pin actuator may include that the interior surface of the hub portion defines a plurality of arcuate faces distributed circumferentially about the rotation axis. The plurality of arcuate faces may be substantially parallel to the rotation axis.

In addition to one or more of the features described above, or as an alternative, further examples of the lift pin actuator may include that one or more of the plurality of planar faces is bounded by an arcuate periphery having a base proximate the lower surface of the hub portion and an open end proximate the upper aperture of the hub portion. One or more of the plurality of planar faces defining a relief channel therein extending from the open end to a location intermediate the open end and the base of the arcuate periphery.

In addition to one or more of the features described above, or as an alternative, further examples of the lift pin actuator may include that the hub portion of the actuator body has an annular segment and a plurality of merlon segments. The plurality of merlon segments may extend axially from the annular segment of the actuator body. The plurality of merlon segments may axially separate the first arm portion and the second arm portion from the annular segment of the hub portion of the actuator body.

In addition to one or more of the features described above, or as an alternative, the actuator body may be formed from (e.g., consist of or consist essentially of) a ceramic material. The ceramic material may be fused silica, quartz, or sapphire.

An actuator arrangement is provided. The actuator arrangement includes an actuator tube member arranged along a rotation axis and a lift pin actuator as described above seated on the actuator tube member. The actuator tube member has an exterior surface defining a plurality of planar facets that are distributed circumferentially about the rotation axis. The lift pin actuator has an interior surface with a plurality of planar faces that are distributed circumferentially about the rotation axis. Each of the plurality of planar faces defined by the interior surface of the actuator member abuts a respective one of the plurality of planar facets defined by the exterior surface of the actuator tube member such that the pin actuator constrained on the actuator tube member.

In addition to one or more of the features described above, or as an alternative, further examples of the actuator arrangement may include that the exterior surface of the actuator tube member defines three (3) planar facets. The interior surface of the lift pin actuator may define three (3) planar faces. Each of the planar faces defined by the interior surface of the hub portion of the actuator body may radially overlap a respective one of the plurality of planar facets defined by the exterior surface of the actuator tube member.

In addition to one or more of the features described above, or as an alternative, further examples of the actuator arrangement may include that the plurality of planar facets are angled relative to the rotation axis at a planar facet angle. The planar facet angle may be between about 5 degrees and about 45 degrees, or between about 5 degrees and about 30 degrees, or between about 5 degrees and about 15 degrees, or even between about 5 degrees and about 10 degrees. The plurality of planar faces may be angled relative to the rotation axis at a planar face angle that is substantially equivalent to the planar facet angle.

In addition to one or more of the features described above, or as an alternative, further examples of the actuator arrangement may include that the exterior surface of the actuator tube member defines a plurality a plurality of arcuate facets, that the interior surface of the lift pin actuator defines a plurality of arcuate faces, and that each of the plurality arcuate faces radially overlaps a respective one of the plurality of arcuate facets.

In addition to one or more of the features described above, or as an alternative, further examples of the actuator arrangement may include that the plurality of arcuate faces defined by the interior surface of the lift pin actuator are radially offset from a respective one of the plurality of arcuate facets defined by the exterior surface of the actuator tube member.

In addition to one or more of the features described above, or as an alternative, further examples of the actuator arrangement may include that the exterior surface of the actuator tube member defines three (3) arcuate facets distributed circumferentially about the rotation axis, and that the interior surface of the lift pin actuator defines three (3) arcuate faces distributed circumferentially about the rotation axis.

In addition to one or more of the features described above, or as an alternative, further examples of the actuator arrangement may include a shaft member arranged within the actuator tube member and supported for rotation about the rotation axis. The plurality of planar facets and the plurality of planar faces may radially overlap the shaft member.

In addition to one or more of the features described above, or as an alternative, the actuator tube member may be formed from (e.g., consist of or consist essentially of) a ceramic material. The ceramic material may be fused silica, quartz, or sapphire.

In addition to one or more of the features described above, or as an alternative, the lift pin actuator may be located on the actuator tube member according to a 3-2-1 locating method and clamped one the actuator tube member with gravity.

A semiconductor processing system is provided. The semiconductor processing system includes a chamber body and a lift pin actuator as described above arranged within the chamber body. An actuator tube member extends through a lower wall of the chamber body, the lift pin actuator seated on the actuator tube member, and a shaft member is arranged within the actuator tube member and supported for rotation about the rotation axis. A substrate support is seated on the shaft member and a plurality of lift pins are slidably received within the substrate support. The lift pin actuator is arranged axially between the lower wall of the chamber body and the plurality of lift pins to seat and unseat substrates from the substrate support by translating the lift pin actuator along the rotation axis.

A method of making a lift pin actuator is provided. The method includes forming a lift pin actuator body from a singular workpiece body formed from a ceramic material using a boring or drilling operation and a milling operation by defining a hub portion extending about a rotation axis; defining a first arm portion and a second arm portion extending outward from the hub portion and in a direction opposite the rotation axis, the second arm portion parallel to the first arm portion; defining a pad portion radially separated from the hub portion by the first arm portion and the second arm portion coupling the first arm portion to the second arm portion; and defining an engagement surface of the pad portion orthogonal relative to the rotation axis and coplanar with the first arm portion and the second arm portion of the actuator body, whereby the engagement surface configured to drive a lift pin above the engagement surface of the pad portion of the actuator body along the rotation axis.

A method of making an actuator arrangement is provided. The method includes, at a lift pin actuator as described above, positioning the actuator body relative to the actuator tube member at three contact points located on the actuator tube member and in a first plane orthogonal relative to the rotation axis, the three contact points distributed about the rotation axis; positioning the actuator body relative to the actuator tube member at a fourth and a fifth contact points located on the actuator tube member and in a second plane parallel to the rotation axis and parallel to the rotation axis and orthogonal to the first plane; positioning the actuator body relative to the actuator tube member at a sixth contact point located on the actuator tube member and in a third plane parallel to the rotation axis and orthogonal relative to both the first plane and the second plane; and clamping the actuator body to the actuator tube member using gravity, whereby the lift pin actuator is constrained relative to the actuator tube member in translation and in rotation within the first plane, the second plane, and the third plane.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a lift pin actuator in accordance with the present disclosure, showing the lift pin actuator arranged and an actuator tube member arranged within a chamber arrangement of a semiconductor processing system;

FIG. 2 is a schematic view of a portion of the semiconductor processing system of FIG. 1 according to an example of the present disclosure, showing a process fluid source connected to the chamber arrangement to provide a process fluid to the chamber arrangement;

FIG. 3 is schematic view of a portion of the semiconductor processing system of FIG. 1 according to an example of the disclosure, showing the chamber arrangement including the lift pin actuator and an actuator tube member seating the lift pin actuator thereon;

FIGS. 4-7 are schematic side views of the chamber arrangement of FIG. 1 according to an example of the disclosure, sequentially showing the lift pin actuator seating a substrate within the chamber arrangement prior to processing and unseating the substrate after processing;

FIG. 8 is a side elevation view of a portion of the chamber arrangement of FIG. 1 including the lift pin actuator according to the present disclosure, showing the lift pin actuator seated on the actuator tube member and a shaft member seating a support member extending through the lift pin actuator and the actuator tube member;

FIG. 9 is an exploded view of a portion of the chamber arrangement of FIG. 1 including the lift pin actuator according to the present disclosure, showing the lift pin actuator and shaft member as well as the support member exploded away from the actuator tube member;

FIGS. 10-12 are views of the lift pin actuator of FIG. 1 according to an example of the present disclosure, showing a pad portion coupled to a hub portion by a first arm portion and a second arm portion of the lift pin actuator;

FIGS. 13 and 14 are lateral and longitudinal cross-sectional views of the lift pin actuator of FIG. 1 according to an example of the present disclosure, showing planar faces with relief channels and arcuate peripheries of the planar faces, respectively;

FIGS. 15 and 16 are side elevation and top plan views of the actuator tube member of FIG. 1 according to an example of the present disclosure, showing a seat end of the actuator member having planar facets to seat the lift pin actuator thereon;

FIGS. 17 and 18 are side elevation and top plan views of the seat end of the actuator tube member of FIG. 1 according to an example of the present disclosure, showing a relief channel and the planar face abutting a planar facet of the actuator tube member, respectively;

FIG. 19 is a block diagram of a method of making a lift pin actuator arrangement in accordance with the present disclosure, showing operations of the method according to an illustrative and non-limiting example of the method; and

FIG. 20 is a block diagram of a method of making an actuator arrangement in accordance with the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

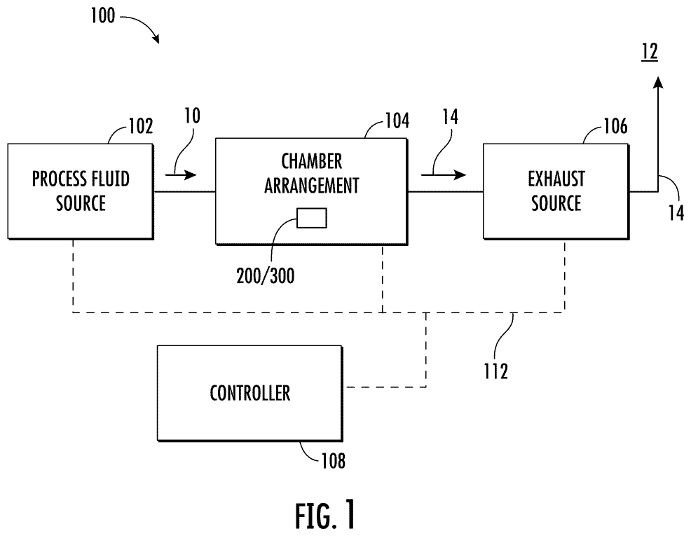

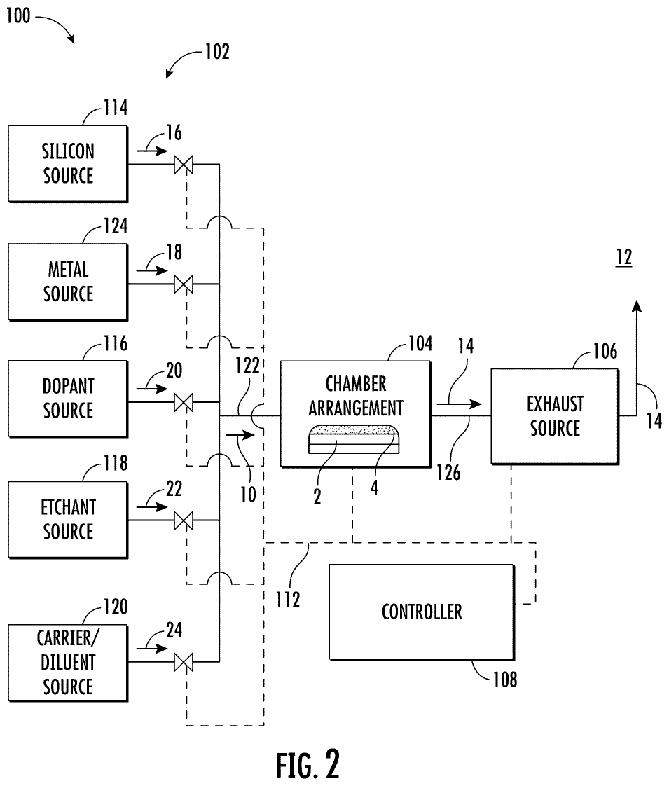

Reference will now be made to the drawings wherein like reference numerals identify similar structural features or aspects of the subject disclosure. For purposes of explanation and illustration, and not limitation, a partial view of an example of a lift pin actuator in accordance with the present disclosure is shown in FIG. 1 and is designated generally by reference character 100. Other examples of lift pin actuators, actuator arrangements and semiconductor processing systems including lift pin actuators, and methods of making lift pin actuators and actuator arrangements in accordance with the present disclosure, or aspects thereof, are provided in FIGS. 2-20, as will be described. The systems and methods of the present disclosure may be used to actuate lift pins in semiconductor processing systems, such as in single wafer cold wall chamber arrangements having cross flow architectures employed to deposit silicon-containing material layers onto substrates, though the present disclosure is not limited to any particular chamber arrangement or to semiconductor processing systems employed to deposit material layers onto substrates in general.

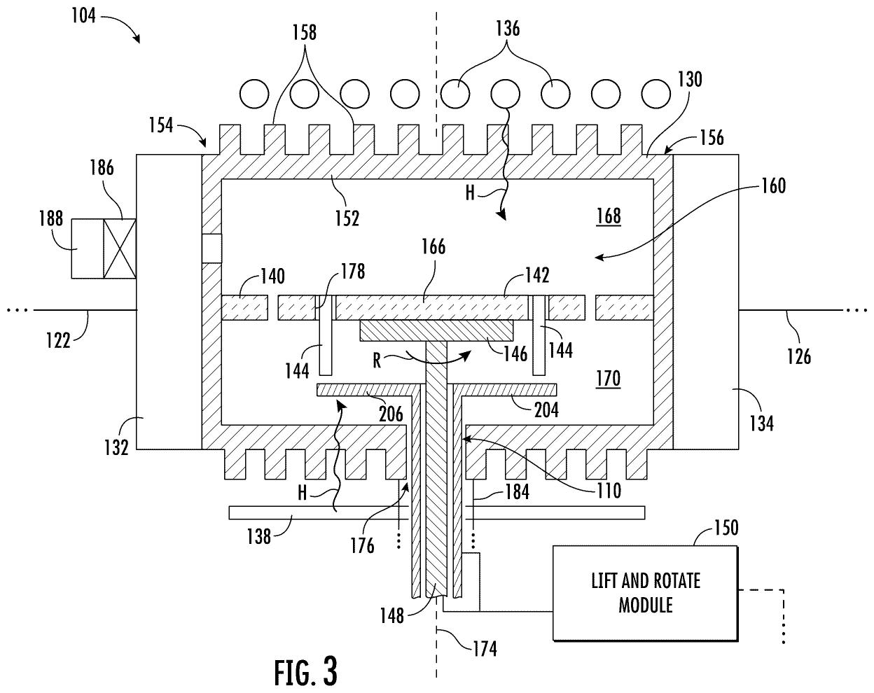

Referring to FIG. 1, a semiconductor processing system 100 is shown. The semiconductor processing system 100 generally includes a process fluid source 102, a chamber arrangement 104, an exhaust source 106, and a controller 108. The process fluid source 102 is configured to communicate a process fluid 10 to the chamber arrangement 104. The chamber arrangement 104 in turn couples the process fluid source 102 to the exhaust source 106, includes a lift pin actuator 200 and an actuator tube member 300, and may be configured to communicate the process fluid 10 to a substrate, e.g., a substrate 2 (shown in FIG. 3), seated in the chamber arrangement 104 using the lift pin actuator 200. The exhaust source 106 couples the chamber arrangement 104 to an external environment 12 outside of the semiconductor processing system 100, for example through a vacuum pump and/or an abatement device such as a scrubber and is configured to communicate a flow of residual process fluid and/or reaction products to the. It is contemplated that the controller 108 be operably coupled to one or more of the process fluid source 102, the chamber arrangement 104, and the exhaust source 106 by a wired or wireless link 112, for example to operate the lift pin actuator 200 and/or control processing of substrates within the chamber arrangement 104.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing.

A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the semiconductor processing system 100 is shown according to an example of the present disclosure. In the illustrated example the semiconductor processing system 100 is configured to deposit a silicon-containing material layer 4 onto the substrate 2 using an epitaxial technique using the process fluid source 102 and includes a silicon-containing material layer precursor source 114, a dopant-containing material layer precursor source 116, an etchant source 118, and a carrier/diluent fluid source 120. The silicon-containing material layer precursor source 114 includes a silicon-containing material layer precursor 16 and is coupled to the chamber arrangement 104 by a process fluid supply conduit 122. The silicon-containing material layer precursor source 114 is further configured to communicate a flow of the silicon-containing material layer precursor 16 to the chamber arrangement 104 and in this respect may be coupled to the chamber arrangement 104 through one or more mass flow control device, e.g., a mass flow controller (MFC) device, operatively associated with the controller 108.

In certain examples the silicon-containing material layer precursor 16 may include a non-halogenated silicon-containing material layer precursor. Non-limiting examples of suitable non-halogenated silicon-containing material layer precursors include silane (SiH₄), disilane (Si₂H₆), trisilane (H₈Si₃), and tetrasilane (Si₄H₁₀). In accordance with certain examples, the silicon-containing material layer precursor 16 may include a halogenated silicon-containing material layer precursor. Non-limiting examples of suitable halogenated silicon-containing material layer precursors include chlorosilane (SiH₃Cl), dichlorosilane (H₂SiCl₂), and trichlorosilane (HCl₃Si). It is contemplated that the silicon-containing material layer precursor source 114 may include two or more of the aforementioned silicon-containing material layer precursors and be configured to communicate the two or more silicon-containing material layer precursors to the chamber arrangement 104. It is also contemplated that the silicon-containing material layer precursor source 114 may cooperate with a metal-containing material layer precursor source 124 including a metal-containing material layer precursor 18 and configured to provide a flow of the metal-containing material layer precursor 18 to the chamber arrangement 104. Examples of suitable metal-containing material layer precursors include germanium (Ge) and gallium (Ga), for example as provided to the chamber arrangement 104 via flow of germane (GeH₄) and/or gallium trichloride (GaCl₃) from the metal-containing material layer precursor source 124.

The dopant-containing material layer precursor source 116 is similar to the silicon-containing material layer precursor source 114, additionally include a dopant-containing material layer precursor 20 and be configured to communicate a flow of the dopant-containing material layer precursor 20 to the chamber arrangement 104. In certain examples the dopant-containing material layer precursor 20 may include a p-type dopant. Examples of suitable p-type dopants include boron (B) and indium (In). In accordance with certain examples, the dopant-containing material layer precursor 20 may include an n-type dopant. Examples of suitable n-type dopants includes phosphorous (P) and arsenic (As). It is also contemplated that the dopant-containing material layer precursor source may include a carbon (C) and remain within the scope of the present disclosure. As will be appreciated by those of skill in the art in view of the present disclosure, other dopants may be employed and remain within the scope of the present disclosure.

The etchant source 118 is similar to silicon-containing material layer precursor source 114, additionally includes an etchant 22, and is further configured to communicate the etchant 22 to the chamber arrangement 104. In certain examples the etchant 22 may include chlorine-containing etchant. For example, the etchant 22 may include hydrochloric (HCl) acid and/or chlorine (Cl₂) gas. In accordance with certain examples, the etchant 22 may include a fluorine-containing etchant. Examples of suitable fluorine-containing etchant include hydrofluoric (HF) acid and fluorine (F₂) gas. It is contemplated that the etchant source 118 may be configured to provide the etchant 22 to the chamber arrangement 104 intermixed with the silicon-containing material layer precursor 16 and/or independent of the silicon-containing material layer precursor 16, for example as cleaning or purge fluid. As will be appreciated by those of skill in view of the present disclosure, other etchants may be included in the etchant source 118 and remain within the scope of the present disclosure.

The carrier/diluent fluid source 120 is similar to the silicon-containing material layer precursor source 114, additionally includes a carrier/diluent fluid 24, and is further configured to provide a flow of the carrier/diluent fluid 24 to the chamber arrangement 104. In certain examples the carrier/diluent fluid source 120 may be configured to provide the carrier/diluent fluid 24 to the chamber arrangement 104 intermixed with one or more of the silicon-containing material layer precursor 16, the metal-containing material layer precursor 18, the dopant-containing material layer precursor 20, and the etchant 22. In accordance with certain examples, the carrier/diluent fluid source 120 may be configured to provide the carrier/diluent fluid 24 to chamber arrangement 104 independently of one or more of the aforementioned fluids. Examples of suitable carrier/diluent fluids include hydrogen (H₂) gas and inert gases like nitrogen (N₂) gas, argon (Ar) gas, and mixtures including one or more of the aforementioned fluids.

The exhaust source 106 is coupled to the chamber arrangement 104 by a process fluid exhaust conduit 126 and is configured to maintain a predetermined pressure within the chamber arrangement 104. In certain examples the exhaust source 106 may be configured to maintain a pressure within the chamber arrangement 104 within a pressure range suitable for atmospheric pressure processing, such as between about 760 Torr and about 710 Torr. In accordance with certain examples, the exhaust source 106 may be configured to maintain a pressure within the chamber arrangement 104 within a pressure range suitable for reduced pressure processing, for example between about 710 Torr and about 0.1 Torr. As used herein the term processing may refer to processing operations during which material layers are deposited onto substrates, processing operations during which material is removed from a substrate, and processing operations during which material layers are deposited and material removed from a substrate seated with the chamber arrangement 104.

With reference to FIG. 3, the chamber arrangement 104 is shown according to an example of the disclosure. In the illustrated example the chamber arrangement 104 has a single-wafer crossflow architecture 128 and includes a chamber body 130, an injection flange 132, and an exhaust flange 134. The chamber arrangement 104 also includes an upper heater element array 136, a lower heater element array 138, and a divider 140. As shown and described herein the chamber arrangement 104 also includes a substrate support 142 with a plurality of lift pins 144 slidably received therein, a support member 146, a shaft member 148, and a lift and rotate module 150. Although shown and described herein as having a specific arrangement and including certain elements, it is to be understood and appreciated that the chamber arrangement 104 may have a different arrangements, as well as include additional elements or exclude elements shown and described herein and remain within the scope of the present disclosure.

The chamber body 130 is formed from a ceramic material 152, e.g., a ceramic material transparent to electromagnetic radiation in an infrared waveband and has an injection end 154 and a longitudinally opposite exhaust end 156. Examples of suitable ceramic materials include quartz, fused silica, and sapphire. In certain examples the chamber body 130 may have a substantially planar upper wall and/or a substantially planar lower wall. In such examples the chamber body 130 may further have a plurality of external ribs 158 extending laterally about the exterior of the chamber body 130 and longitudinally spaced apart from one another between the injection end 154 and the exhaust end 156 of the chamber body 130. In accordance with certain examples, either (or both) the upper wall and the lower wall of the chamber body 130 may be arcuate or dome-like in shape and remain within the scope of the present disclosure.

The injection flange 132 abuts the injection end 154 of the chamber body 130 and fluidly couple the process fluid source 102 (shown in FIG. 1) to an interior 160 of the chamber body 130. In this respect the process fluid supply conduit 122 may connect the process fluid source 102 to the injection flange 132 to communicate the process fluid 10 into the interior 160 of the chamber body 130. The exhaust flange 134 abuts the exhaust end 156 of the chamber body 130 and fluidly couple the interior 160 of the chamber body 130 to the exhaust source 106 (shown in FIG. 1). In this regard the process fluid exhaust conduit 126 may connect the exhaust flange 134 to the exhaust source 106 to communicate the residual process fluid and/or reaction products to the exhaust source 106. In certain examples, the injection flange 132 may be as shown and described in U.S. Pat. No. 11,053,591 to Ma et al., issued on Jul. 6, 2021, the contents of which is incorporated herein by reference in its entirety. In accordance with certain examples, the exhaust flange 134 may be as shown and described in U.S. Pat. No. 10,612,136 to Sreeram et al., issued on Apr. 7, 2020, the contents of which is incorporated herein by reference in its entirety.

The upper heater element array 136 is supported above the chamber body 130 and includes a plurality of upper heater elements 162. It is contemplated that the upper heater elements 162 be operably associated with the controller 108 (shown in FIG. 1) and configured to communicate heat H into the interior 160 of the chamber body 130. In certain examples plurality of upper heater elements 162 may each include a linear filament, extend laterally across the upper wall of the chamber body 130, and longitudinally spaced apart from one another between the injection end 154 and the exhaust end 156 of the chamber body 130. In accordance with certain examples, the plurality of upper heater elements 162 may extend longitudinally between the injection end 154 and the exhaust end 156 of the chamber body 130, the plurality of upper heater elements 162 laterally spaced apart from one another between laterally opposite side walls of the chamber body 130. The lower heater element array 138 may be similar to the upper heater element array 136 and additionally include a plurality of lower heater elements 164 each supported below the lower wall of the chamber body 130. In certain examples the plurality of lower heater elements may be substantially orthogonal relative to the plurality of upper heater elements 162. Although shown and described herein as including linear filament-type heater elements, it is to be understood and appreciated that either (or both) the upper heater element array 136 and the lower heater element array 138 may include bulk-type heater elements and remain within the scope of the present disclosure.

The divider 140 is formed from an opaque material 166 (e.g., a material opaque to electromagnetic radiation in an infrared waveband) and is supported within the interior 160 of the chamber body 130. It is contemplated that the divider 140 divide the interior 160 of the chamber body 130 into an upper chamber 168 and the lower chamber 170. It is also contemplated that the divider 140 define a divider aperture 172 therethrough and that the divider aperture 172 fluidly coupling the upper chamber 168 to the lower chamber 170. It is further contemplated that the substrate support 142 be arranged within the interior 160 of the chamber body 130 at least partially within the divider aperture 172 and be supported therein for rotation R about a rotation axis 174. In certain examples the opaque material 166 may include a bulk carbonaceous material, such pyrolytic carbon or graphite with a ceramic coating. In accordance with certain examples, the opaque material 166 may include a bulk ceramic material, such as silicon carbide by way of example and not limitation. It is contemplated that the substrate support 142 may also be formed (at least in part) from the opaque material 166.

The support member 146 is arranged along the rotation axis 174 and within the lower chamber 170 of the chamber body 130 and is fixed relative to the substrate support 142. It is contemplated that the support member 146 be formed from a material transparent to electromagnetic radiation within an infrared waveband, for example the ceramic material 152. The shaft member 148 is also arranged along the rotation axis 174 and is additionally fixed in rotation relative to the support member 146 in rotation about the rotation axis 174. The shaft member 148 further extends through a passthrough 176 defined within the lower wall of the chamber body 130 and into the external environment outside of the chamber body 130, and operably couples the lift and rotate module 150 the substrate support 142 to rotate the substrate support 142 via the shaft member 148 and the support member 146 about the rotation axis 174. In certain examples the shaft member 148 may be formed from a material transparent to electromagnetic radiation within an infrared waveband, such as the ceramic material 152.

The plurality of lift pins 144 are slidable received within the respective lift pin apertures 178 defined within the substrate support 142. It is contemplated that the plurality of lift pins 144 be configured to seat and unseat substrates, e.g., the substrate 2, from the substrate support 142 and this respect are supported within the interior 160 of chamber body 130 at location above a lift pin actuator 200 and an actuator tube member 300 relative to gravity. The lift pin actuator 200 is arranged along the rotation axis 174 within (at least in part) the lower chamber 170 of the chamber body 130, is seated on the actuator tube member 300, and is translatable along the rotation axis 174 between a retracted position 180 and an extended position 182 along the rotation axis 174. The actuator tube member 300 seats the lift pin actuator 200 thereon, extends through the passthrough 176 into the external environment outside of the chamber body 130.

It is contemplated that the actuator tube member 300 be supported for translation relative to the shaft member 148 along the rotation axis 174 to drive the lift pin actuator 200 between the retracted position 180, wherein the lift pin actuator 200 is proximate the lower wall of the chamber body 130 such that the lift pins dangle below the substrate support 142 within the lower chamber 170 of the chamber body 130, and the extended position 182, wherein the lift pin actuator 200 is proximate the substrate support 142 and in abutment with the plurality of lift pins 144 such that each of the plurality of lift pins 144 protrude above the substrate support 142 and into the upper chamber 168 of the chamber body 130. Translation of the actuator tube member 300 and thereby by the lift pin actuator 200 may be through operable association of the lift and rotate module 150. In certain examples either (or both) the lift pin actuator 200 and the actuator tube member 300 may be formed from (e.g., consist of or consist essentially of) a ceramic material, such as the ceramic material 152. In accordance with certain examples, an exterior surface of the shaft member 148 and an interior surface of the actuator tube member 300 may be radially spaced apart from one another to define an annular flow area therebetween. It is also contemplated a tubulation member 184 may be fixed to the lower wall of the chamber body 130 and about the passthrough 176, the actuator tube member 300 and the shaft member 148 arranged at least partially in the tubulation member 184.

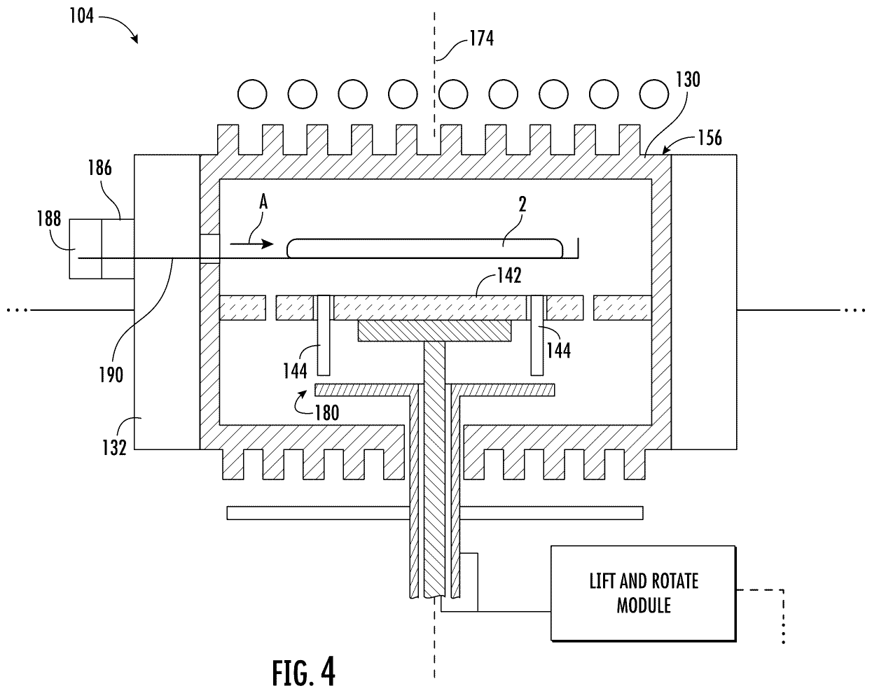

With reference to FIGS. 4-8, loading and seating of the substrate 2 within the chamber arrangement 104 prior to processing of the substrate 2, processing (e.g., deposition of the material layer 4) of the substrate 2, and unseating and unloading of the substrate 2 from the chamber arrangement 104 subsequent to processing are sequentially shown. As shown in FIG. 4, loading of the substrate 2 into the chamber arrangement 104 is accomplished by opening a gate valve 186 connected to the injection flange 132 of the chamber arrangement 104, advancing an end effector 190 carrying the substrate 2 into the upper chamber 168 of the chamber body 130 using a substrate transfer robot 188 coupled to the chamber body 130. It is contemplated that the substrate transfer robot 188 advance A the end effector 190 longitudinally into the upper chamber 168 and toward the exhaust end 156 of the chamber body 130 until the substrate 2 is centered about the rotation axis 174 at a location above the substrate support 142 and the plurality of lift pins 144. So positioned, the substrate may be seated on the substrate support 142.

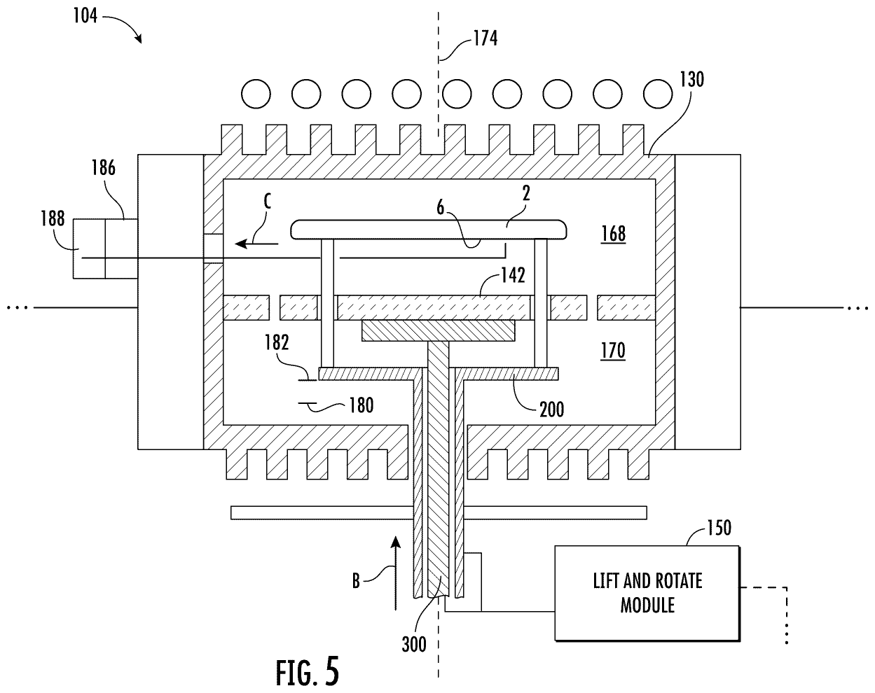

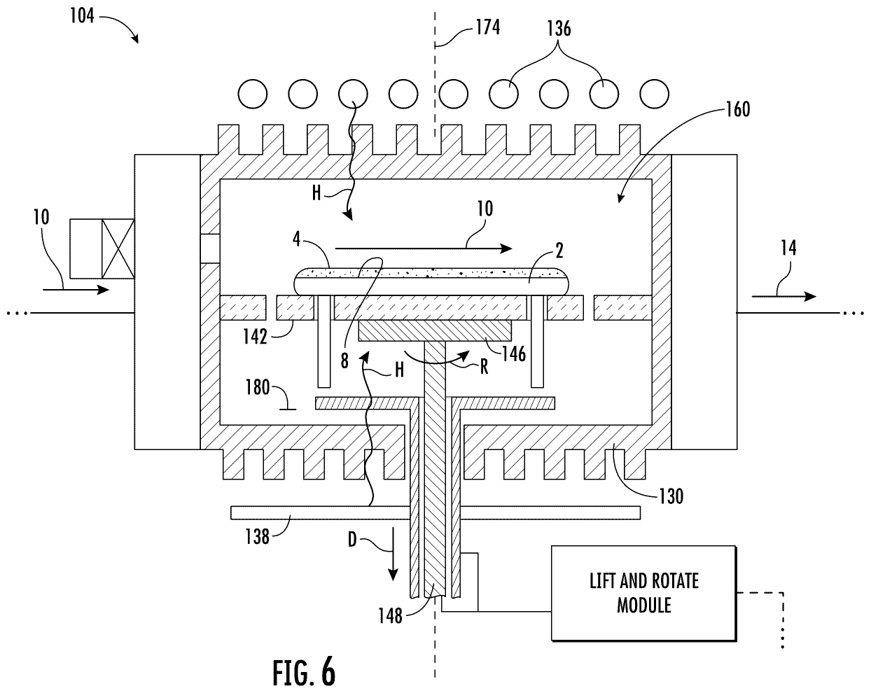

As shown in FIG. 5, seating of the substrate 2 on the substrate support 142 is accomplished by driving B the lift pin actuator 200 from the retracted position 180 to the extended position 182. In this respect it is contemplated that the lift and rotate module 150 drive the actuator tube member 300 (and thereby the lift pin actuator 200 seated thereon) axially along the rotation axis 174 within the lower chamber 170 of the chamber body 130 upwards, in a direction toward the substrate support 142. As the lift pin actuator 200 translates upward within the lower chamber 170 the lift pin actuator 200 comes into contact with end of the plurality of lift pins 144 dangling into the lower chamber 170 from the substrate support 142. Further translation thereafter drives the plurality of lift pins 144 through the substrate support 142 such that the plurality of lift pins 144 protrude above the substrate support 142, the plurality of lift pins 144 coming into contact with an underside of the substrate 2. As the plurality of lift pins 144 are in contact with the underside 6 of the substrate 2 further translation of the lift pin actuator 200 causes the substrate 2 to transfer from the end effector 190 to the plurality of lift pins 144 as the plurality of lift pins 144 approach the extended position 182. The substrate transfer robot 188 may thereafter withdraw C the end effector 190 from the upper chamber 168 of the chamber body 130, the gate valve 186 closed, and the lift pin actuator 200 translated downward D (shown in FIG. 6) within the lower chamber 170 in a direction axially opposite the substrate support 142 toward the retracted position 180. As the lift pin actuator 200 translates downward, the plurality of lift pins 144 translate downward through the substrate support 142 by operation of gravity, the substrate 2 thereby transferring to the substrate support 142 as the plurality of lift pins 144 approach the retracted position 180. The substrate 2 may be processed within the chamber arrangement 104 (e.g., withing the chamber body 130) to deposit the material layer 4 onto the substrate 2.

As shown in FIG. 6, processing of the substrate 2 may be accomplished by heating the substrate 2 to a predetermined material layer deposition temperature, for example to a temperature that is between about 200 degrees Celsius about 1200 degrees Celsius, using either (or both) the upper heater element array 136 and the lower heater element array 138. Processing of the substrate 2 may further be accomplished by establishing—and thereafter maintaining—a predetermined material layer deposition pressure within the interior 160 of the chamber body 130, for example, using a vacuum pump included in the exhaust source 106 (shown in FIG. 1). In this respect it is contemplated that pressure within the interior 160 of the chamber body 130 be maintained within a range that is between about 01. Torr and 760 Torr, for example between about 760 Torr and about 720 Torr (for deposition of the material layer 4 using an atmospheric technique) or between about 720 Torr and about 0.1 Torr (for deposition of the material layer 4 using a reduced pressure technique). The substrate support 142 with the substrate 2 seated thereon may further be rotated about the rotation axis 174 by the lift and rotate module 150 using rotation R communicated to the substrate support 142 through the shaft member 148 and the support member 146, for example at a predetermined material layer deposition rotational speed.

It is contemplated that an upper surface 8 of the substrate 2 be exposed to the process fluid 10 while the substrate is maintained at the predetermined deposition temperature and the interior 160 of the chamber body 130 maintained at the predetermined deposition pressure. It is also contemplated that the process fluid 10 in turn include the silicon-containing material layer precursor 16 (shown in FIG. 2) and one or more of the metal-containing material layer precursor 18 (shown in FIG. 2), the dopant-containing material layer precursor 20 (shown in FIG. 2), the etchant 22 (shown in FIG. 2), and the carrier/diluent fluid 24 (shown in FIG. 2), the material layer 4 thereby being a silicon-containing material layer, the material layer 4 further being epitaxial with the substrate 2 in certain examples of the present disclosure. It is further contemplated that the flow of the process fluid 10 cease once the material layer 4 develop one or more predetermined property (e.g., thickness and/or resistivity), rotation of the substrate support 142 about the rotation axis 174 cease, and that heating of the substrate and pressure within the interior 160 of the chamber body 130 be adjusted such that substrate 2 with the material layer 4 deposited thereon may be unseated from the substrate support 142 and unloaded from the chamber body 130.

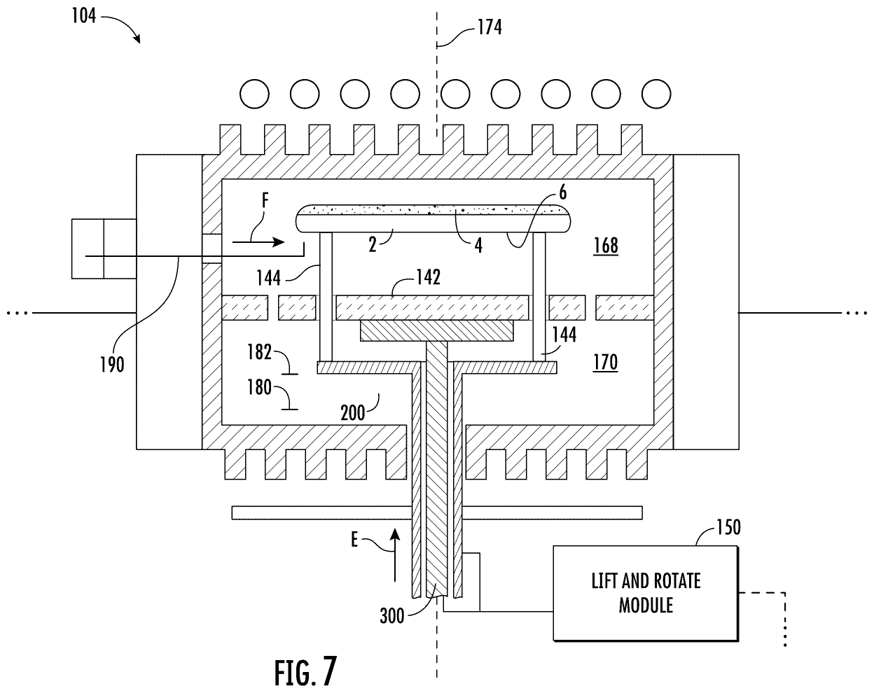

As shown in FIG. 7, unseating of the substrate 2 from the substrate support 142 may be accomplished by once again translating the lift pin actuator 200 from the retracted position 180 to the extended position 182. In this respect it is contemplated that the lift and rotate module 150 again drive E the actuator tube member 300 (and thereby the lift pin actuator 200 seated thereon) axially along the rotation axis 174 within the lower chamber 170 toward the substrate support 142. As the lift pin actuator 200 translates upward within the lower chamber 170 the lift pin actuator 200 comes into contact with end of the plurality of lift pins 144 dangling into the lower chamber 170 from the substrate support 142. Further translation of the lift pin actuator 200 thereafter drives the plurality of lift pins 144 through the substrate support 142 such that the plurality of lift pins 144 come into contact with the underside 6 of the substrate 2. Continuing translation of the lift pin actuator 200 along the rotation axis 174 causes the plurality of lift pins 144 to protrude from the substrate support 142 into the upper chamber 168 of the chamber body 130, unseating the substrate 2 from the substrate support 142, the substrate 2 ultimately supported above the substrate support 142 at a position where the end effector 190 may again be advanced F into the upper chamber 168 to a position axially between the substrate 2 and the substrate support 142 once the lift pin actuator 200 reaches the extended position 182. So positioned, the substrate may be unloaded from the chamber arrangement 104.

Unloading of the substrate 2 with the material layer 4 deposited thereon may be accomplished by again opening the gate valve 186. Once the gate valve 186 is open the substrate transfer robot 188 may again advance the end effector 190 longitudinally into the chamber body 130 toward the exhaust flange 134. In this respect it is contemplated that the end effector 190 be positioned such that the end effector 190 is below the substrate 2, axially spaced apart from both the underside 6 of the substrate 2 and the substrate support 142, and registered to the substrate 2 such that movement of the lift pin actuator from the extended position 182 toward the retracted position 180 causes the substrate 2 to transfer to the end effector 190. Once the end effector 190 is positioned the lift in rotate module 150 may translate the actuator tube member 300 (and the lift pin actuator 200 seated thereon) downward along the rotation axis 174. Downward translation of the actuator tube member 300 translates the lift pin actuator 200 from the extended position 182, the plurality of lift pins 144 sliding downwards through the substrate support 142 by operation of gravity, and the substrate 2 transferring from the plurality of lift pins 144 to the end effector 190 as the plurality of lift pins 144 seat in the substrate support 142 and dangle therefrom into the lower chamber 170 of the chamber body 130. The substrate transfer robot 188 may then withdraw the end effector 190 carrying the substrate 2 with the material layer 4 deposited thereon from the upper chamber 168, the gate valve 186 be closed, and the chamber arrangement 104 prepared for processing a subsequent substrate.

One challenge to operation of chamber arrangements with lift pin actuators is that the lift pin actuator may need to be oversized in relation to a size otherwise preferable due to tendency of the lift pin actuator to shadow the underside of the substrate support. For example, the lift pin actuator have a circumferential extent greater than otherwise desirable due to error in registration of the lift pins relative to the lift pin actuator at the end of deposition. The lift pin actuator may further have a greater radial extent than otherwise desirable due to tendency of the lift pin actuator to pitch and/or roll about the end of the actuation actuator tube member upon engagement of the lift pins. The tendency of the lift pin actuator to pitch and/or roll may be exacerbated in deposition processes wherein the substrate support is precoated, of the lift pins themselves prone to accretion during deposition, such precoats and accretions increasing force required to drive the lift pins during movement in an asymmetric way. To limit shading of the underside of the substrate support 142 and/or limit lift pin actuator displacement in processes employing precoats and/or which may be subject to accretion formation within the chamber body 130 on components such as the plurality of lift pins 144, the lift pin actuator 200 and the actuator tube member 300 are provided.

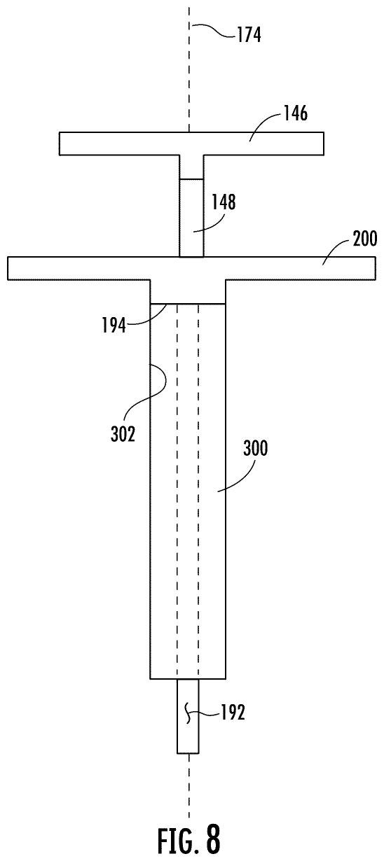

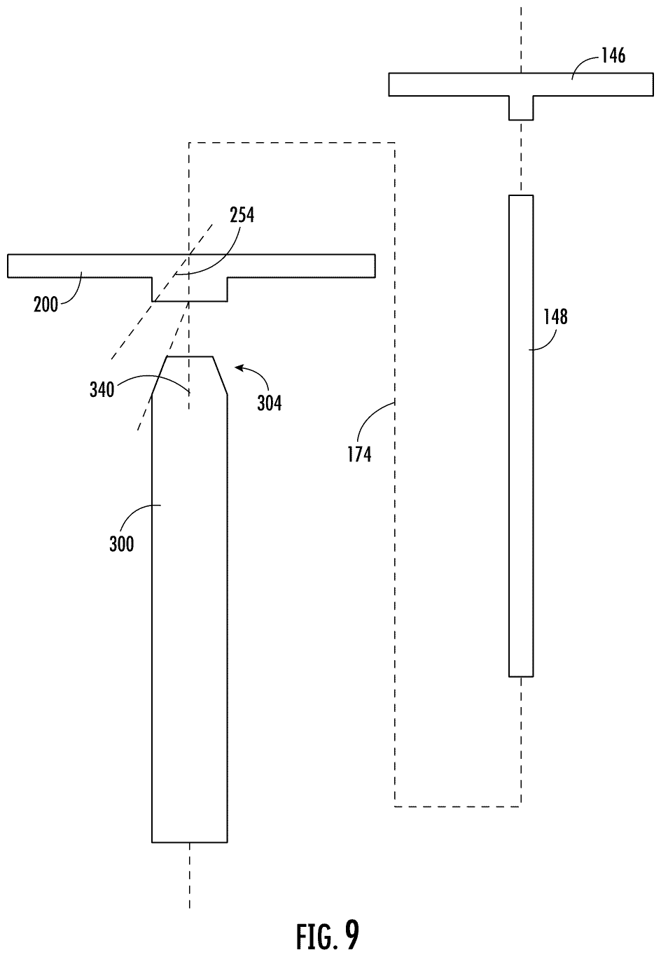

With reference to FIGS. 8 and 9, a portion of the chamber arrangement 104 is shown including the lift pin actuator 200 and the actuator tube member 300 are shown. As shown in FIG. 9, the lift pin actuator 200 is arranged along the rotation axis 174, extends about the rotation axis 174, and is axially offset from the support member 146 along the rotation axis 174. The actuator tube member 300 is also arranged along the rotation axis 174, extends about the shaft member 148, and seats thereon of the lift pin actuator 200. The shaft member 148 protrudes axially from the lift pin actuator 200 in a direction axially opposite the actuator tube member 300, seats thereon the support member 146, and radially spaced apart from an interior surface 202 of the actuator tube member 300 such that an exterior surface 192 and the interior surface 202 of the actuator tube member 300 define a radial gap 194 therebetween. It is contemplated that a fluid source, e.g., the carrier/diluent fluid source 120 (shown in FIG. 2), may be connected to the actuator tube member 300 such that the actuator tube member 300 fluidly couples the fluid source to the lower chamber 170 (shown in FIG. 3) of the chamber body 130 (shown in FIG. 3).

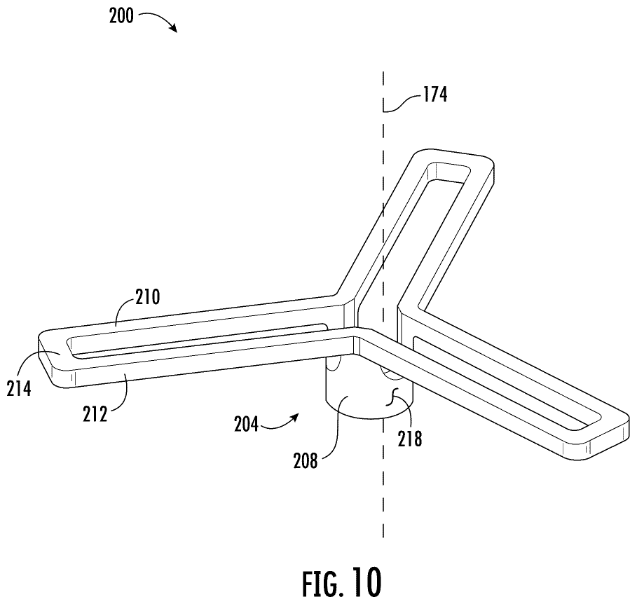

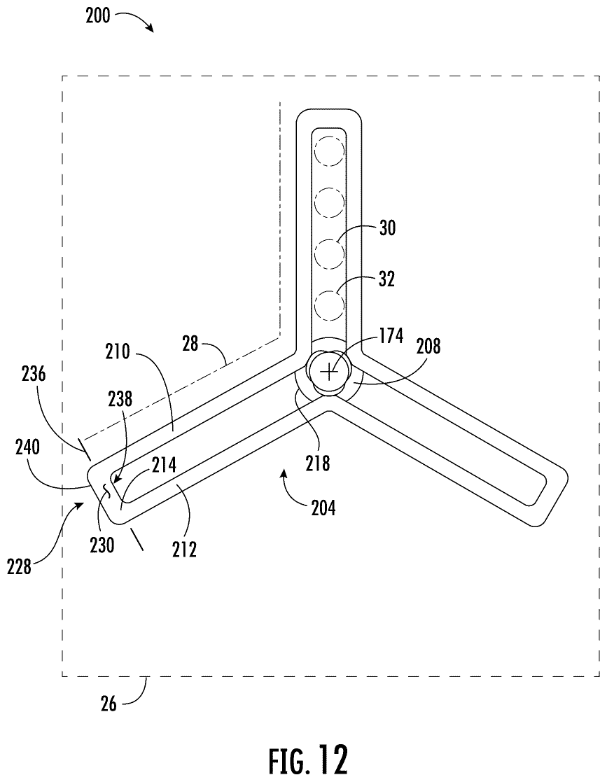

With reference to FIGS. 10-14, the lift pin actuator 200 is shown according to an example of the present disclosure. As shown in FIG. 10, the lift pin actuator 200 generally includes an actuator body 204. The actuator body 204 is configured for translation along the rotation axis 174 within the lower chamber 78 (shown in FIG. 3) of the chamber body 130 (shown in FIG. 3). The actuator body 204 is further formed from a ceramic material 206 (shown in FIG. 3), such as a ceramic material transparent to electromagnetic radiation within an infrared waveband and may consist of or consist essentially of the ceramic material 206. As will be appreciated by those of skill in the art in view of the present disclosure, forming the actuator body 204 from a ceramic material may limit variation within the material layer 4 (shown in FIG. 3) deposited onto the substrate 2 (shown in FIG. 3), for example by limiting cross-substrate temperature non-uniformity during deposition of the material layer 4 onto the substrate 2 due to shading of the underside of the substrate support 142 (shown in FIG. 3) to electromagnetic radiation communicated into the interior 160 (shown in FIG. 3) of the chamber body 130 (shown in FIG. 3) by the lower heater element array 138 (shown in FIG. 3) by the lift pin actuator 200. In certain examples of the present disclosure the ceramic material 206 may be quartz. It is also contemplated that the ceramic material 206 may be fused silica or sapphire and remain within the scope of the present disclosure. In accordance with certain examples, the lift pin actuator 200 may formed from a singular workpiece 26 (shown in FIG. 12) (e.g., a singular ceramic workpiece body) using a subtractive manufacturing technique. For example, the lift pin actuator 200 may be formed using two or more of a cutting or sawing operation 28, a boring or drilling operation 30, and a milling operation 32 by way of non-limiting example. As will be appreciated by those of skill in the art in view of the present disclosure, using two or more subtractive manufacturing techniques may reduce the time required to manufacture the lift pin actuator 200, for example due to relatively high material removal rates of cutting or sawing as well as boring or drilling relative to milling, limiting cost of the semiconductor processing system 100 (shown in FIG. 1) includes the lift pin actuator 200.

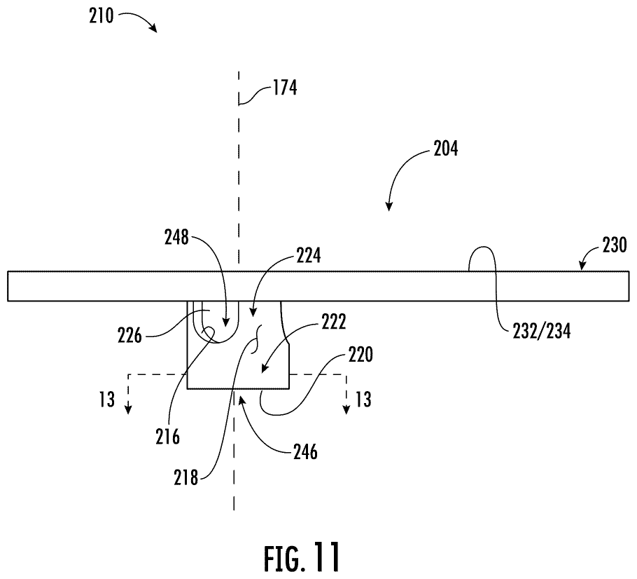

It is contemplated that the lift pin actuator 200 be configured to drive the plurality of lift pins 144 (shown in FIG. 3) and in this respect the actuator body 204 has a hub portion 208, a first arm portion 210 and a second arm portion 212, and a pad portion 214. The hub portion 208 extends about the rotation axis 174 and has an upper surface 216 (shown in FIG. 11), a radial exterior surface 218, and a lower surface 220 (shown in FIG. 11). It is contemplated that the upper surface 216 be angled relative the rotation axis 174 and in this respect the upper surface 216 may be orthogonal relative to the rotation axis 174. The radial exterior surface 218 extends axially from the upper surface 216 along the rotation axis 174 toward the lower surface 220 and about the rotation axis 174, and axially separates the lower surface 220 from the upper surface 216 of the hub portion 208 of the actuator body 204. The lower surface 220 is angled relative to the rotation axis 174 and may be substantially orthogonal relative to the rotation axis 174. In certain examples the lower surface 220 may be wider than the upper surface 216, the hub portion 208 having a generally frustoconical shape in such examples. It is also contemplated that the hub portion 208 may be cylindrical in shape and remain within the scope of the present disclosure.

As shown in FIG. 11, it is contemplated the hub portion 208 of the actuator body 204 may be castellated. In this respect the hub portion 208 has an annular segment 222 and a plurality of merlon segments 224. The annular segment 222 extends axially along the rotation axis 174 and about the rotation axis 174. The annular segment 222 further extends axially between the lower surface 220 to the upper surface 216 of the hub portion 208 of the actuator body 204. The plurality of merlon segments 224 extend axially from the annular segment 222 of the hub portion 208 of the actuator body 204, are distributed about the rotation axis 174, and couple the first arm portion 210 (shown in FIG. 10) and the second arm portion 212 (shown in FIG. 10) to the annular segment 222 of the hub portion 208 of the actuator body 204. It is further contemplated that the plurality of merlon segments 224 axially separate the first arm portion 210 and the second arm portion 212 from the annular segment 222 of the hub portion 208 of the actuator body 204, define between one another a plurality of crenels 226. The plurality of crenels 226 extend axially between the annular segment 222 and the arm portions of hub portion 208 (e.g., the first arm portion 210 and the second arm portion 212), and each separate circumferentially adjacent merlon segments 224 from one another. In the illustrated example the hub portion 208 has three (3) merlon segments 224 circumferentially separated by three (3) crenels 226. As will be appreciated by those of skill in the art in view of the present disclosure, the hub portion 208 may have fewer or additional merlon segments and crenels in other examples and remain within the scope of the present disclosure.

As shown in FIG. 12, the first arm portion 210 and the second arm portion 212 extend outward (e.g., chordwise) from the hub portion 208 and in a direction opposite the rotation axis 174. The second arm portion 212 may further be substantially parallel to the first arm portion 210 and may be orthogonal relative to the rotation axis 174. In certain examples, the first arm portion 210 and the second arm portion 212 may be substantially orthogonal relative to the radial exterior surface 218 of the hub portion 208 of the actuator body 204. In accordance with certain examples, the first arm portion 210 may axially overlap a first the plurality of merlon segments 224 (shown in FIG. 11) and the second arm portion 212 may axially overlap second of the plurality of merlon segments 224, a singular one of the plurality of crenels 226 (shown in FIG. 11) in turn circumferentially separating the second arm portion 212 from the first arm portion 210 of the actuator body 204.

It is contemplated that the first arm portion 210 and the second arm portion 212 form a first arm pair 228. The first arm pair 228 may be one of a plurality of arm pairs extending outward from the hub portion and distributed circumferentially about the rotation axis 174. The plurality of arm pairs may in turn distributed circumferentially about the rotation axis 174, for example symmetrically such that each arm pair is separated from the adjacent arm pair by a common angular offset about the rotation axis 174. In the illustrated example the first arm pair 228 is one of three (3) arm pairs distributed circumferentially about the rotation axis 174 and the hub portion 208 of the actuator body 204. As will be appreciated by those of skill in the art in view of the present disclosure, the actuator body 204 may have fewer or addition arm pairs that shown and described herein and remain within the scope of the present disclosure.

The pad portion 214 of the actuator body 204 is radially separated from the hub portion 208 of the actuator body 204. The pad portion 214 further couples the second arm portion 212 to the first arm portion 210 of the actuator body 204 and has an engagement surface 230. The engagement surface 230 is configured to engage bottom ends of the plurality of lift pins 144 (shown in FIG. 3) and in this respect may be substantially planar. In further respect, it is contemplated that the engagement surface 230 be substantially orthogonal relative to the rotation axis 174. In certain examples, the engagement surface 230 may be coplanar with a first arm portion upper surface 232 (shown in FIG. 11) and a second arm portion upper surface 234 (shown in FIG. 11). In accordance with certain examples, the pad portion 214 may define (e.g., trace) an arcuate segment 236 extending circumferentially about the rotation axis 174. In is contemplated that the pad portion 214 may be bounded by a radially inner pad surface 238 and a radially outer pad surface 240, the radially inner pad surface 238 extending between the first arm portion 210 and the second arm portion 212, the radially outer pad surface 240 extending in parallel with the radially inner pad surface 238 and circumferentially spanning both the first arm portion 210 and the second arm portion 212 of the actuator body 204. In the illustrated example the pad portion 214 is one of three (3) pad portions distributed circumferentially about the rotation axis 174. As will be appreciated by those of skill in the art in view of the present disclosure, the actuator body 204 may include fewer or additional pad portions than shown and described herein and remain within the scope of the present disclosure.

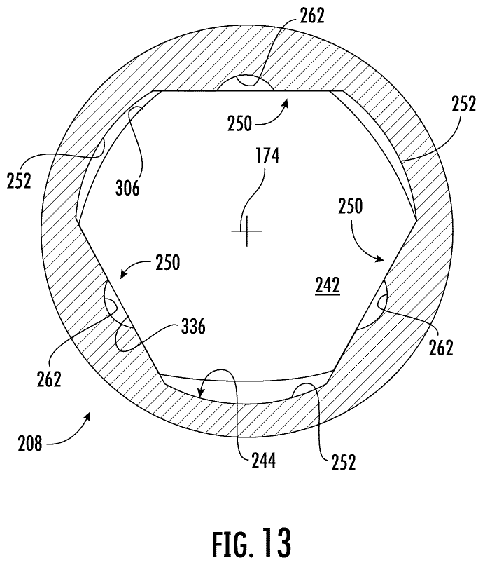

As shown in FIG. 13, it is contemplated that the hub portion 208 of the actuator body 204 be configured for seating onto the actuator tube member 300 (shown in FIG. 3). In this respect the hub portion 208 defines a seating socket 242 within an interior of the hub portion 208 of the actuator body 204. The seating socket 242 is bounded by an interior surface 244 of the hub portion 208, corresponds geometrically to a seat end 304 (shown in FIG. 9) of the actuator tube member 300, and is coupled to the external environment outside of the hub portion 208 by a seating aperture 246 (shown in FIG. 11) defined within the lower surface 220 (shown in FIG. 11) of the hub portion 208, and an upper surface aperture 248 (shown in FIG. 11) defined within the upper surface 216 (shown in FIG. 11) of the hub portion 208 of the actuator body 204. It is contemplated that the interior surface 244 of hub portion 208 bounding the seating socket 242 define a plurality of planar faces 250. It is also contemplated that the interior surface 244 of the hub portion 208 of the actuator body 204 may define a plurality of arcuate faces 252 within the seating socket 242, and that the interior surface 244 couple the upper surface aperture 248 defined in the upper surface 216 to the seating aperture 246 defined in the lower surface 220.

The plurality of planar faces 250 are distributed circumferentially about the rotation axis 174. The plurality of planar faces 250 are further angled relative to the rotation axis 174, each of the plurality of planar faces 250 separated at greater distances from the rotation axis 174 proximate the lower surface 220 of the hub portion 208 than proximate the upper surface 216 of the hub portion 208 of the actuator body 204. In this respect it is contemplated that each of the plurality of planar faces 250 be angled relative to the rotation axis 174 (and/or relative to at least one of the upper surface 216 (shown in FIG. 11) and the lower surface 220 (shown in FIG. 11) of the hub portion 208) at a common planar face angle 254. The common planar face angle 254 may be an oblique angle. In certain examples, the common planar face angle 254 may between about 5 degrees and 45 degrees, or between about 5 degrees and about 30 degrees, or between about 5 degrees and about 15 degrees, or even between about 5 degrees and about 10 degrees. Advantageously, common planar face angles within these angular ranges may limit (or prevent entirely) tendency of the lift pin actuator 200 to fuse the actuator tube member 300 (shown in FIG. 1), for example due to cyclic heating and cooling of the actuator arrangement 110 (shown in FIG. 3) due to sequential processing of substrates within the semiconductor processing system 100, simplifying maintenance of the semiconductor processing system 100 in examples where the lift pin actuator 200 may require periodic removal from the actuator tube member 300 during service events. In the illustrated example the interior surface 244 of the hub portion 208 has three (3) planar surfaces. As will be appreciated by those of skill in the art in view of the present disclosure, the lift pin actuator 200 may have fewer or additional planar faces in other examples and remain within the scope of the present disclosure.

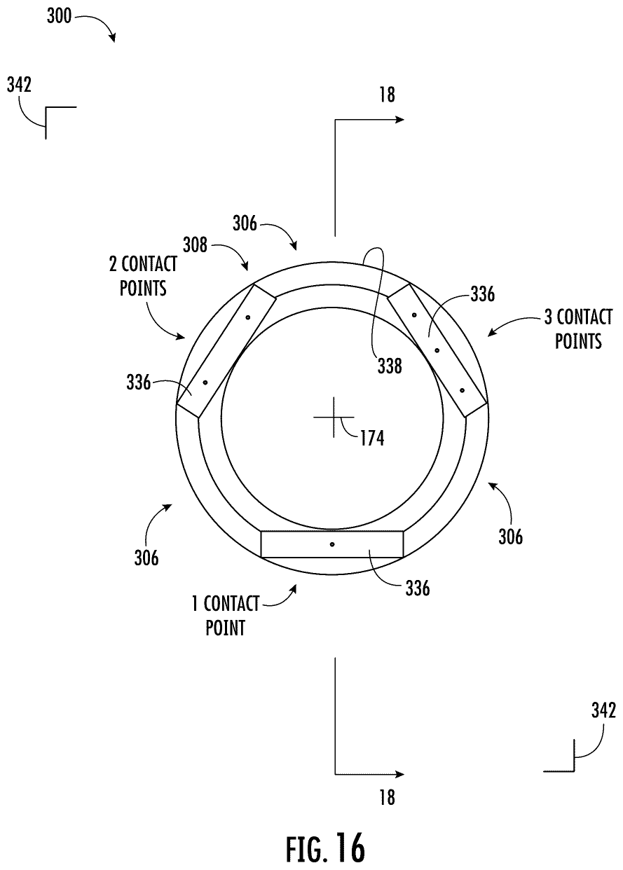

In certain examples one or more of the plurality of planar faces 250 may be bounded by an arcuate periphery 256. The arcuate periphery 256 may have a base 258, proximate the lower surface 220 of the hub portion 208 of the actuator body 204, and an open end 260 proximate the upper surface aperture 248 (shown in FIG. 11) defined within the upper surface 216 of the hub portion 208 of the actuator body 204. In accordance with certain examples, one or more of the plurality of planar faces 250 may have a relief channel 262 defined within the respective planar face 250. The relief channel 262 may extend from the open end 260 of the arcuate periphery 256 toward a location intermediate the open end 260 and the base 258 of the arcuate periphery 256. Advantageously, definition of the relief channel 262 within one or more of the plurality of planar faces 250 can promote stability of the lift pin actuator 200 of the actuator tube member 300 (shown in FIG. 3), for example by spreading contact points between the planar face 250 having the relief channel 262 and an abutting one of the plurality of planar facets 336 (shown in FIG. 16) defined on the seat end 304 (shown in FIG. 9) of the actuator tube member 300. As shown and described herein each of the plurality of planar faces 250 define a singular relief channel 262 therein. As will be appreciated by those of skill in the art in view of the present disclosure, the plurality of planar faces 250 may have fewer or additional relief channels defined therein than shown and described herein and remain within the scope of the present disclosure.

With continuing reference to FIG. 13, the plurality of arcuate faces 252 defined by the interior surface 244 of the hub portion 208 are distributed circumferentially about the rotation axis 174. It is contemplated that individual arcuate faces of the plurality of arcuate faces 252 separate circumferentially adjacent ones of the plurality of planar faces 250, and that circumferentially adjacent ones of the plurality of arcuate faces 252 separated by intermediate ones of the plurality of planar faces 250. In certain examples the plurality of arcuate faces 252 may be substantially parallel to the rotation axis 174. In accordance with certain examples, each of the plurality of arcuate faces 252 may be overcut relative to corresponding arcuate facets 306 defined on the seat end 304 (shown in FIG. 9) of the actuator tube member 300 (shown in FIG. 3), the respective arcuate face 252 and arcuate facet 306 defining a radial clearance therebetween. Advantageously, overcutting the plurality of arcuate faces 252 relative to the plurality of arcuate facets 306 ensures that the plurality of planar faces 250 locate the lift pin actuator 200 on the seat end 304 of the actuator tube member 300, promoting stability of the lift pin actuator 200 on the actuator tube member 300. As shown and described herein the interior surface 244 of the hub portion 208 has three (3) arcuate faces. As will be appreciated by those of skill in the art in view of the present disclosure, the lift pin actuator 200 (shown in FIG. 3) may have fewer or additional arcuate faces in other examples and remain within the scope of the present disclosure.

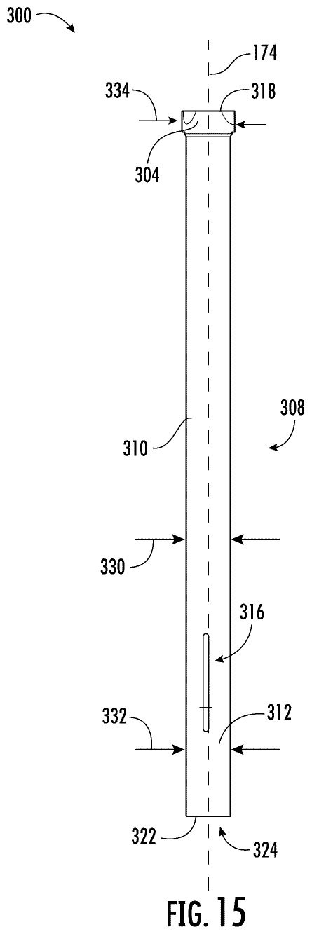

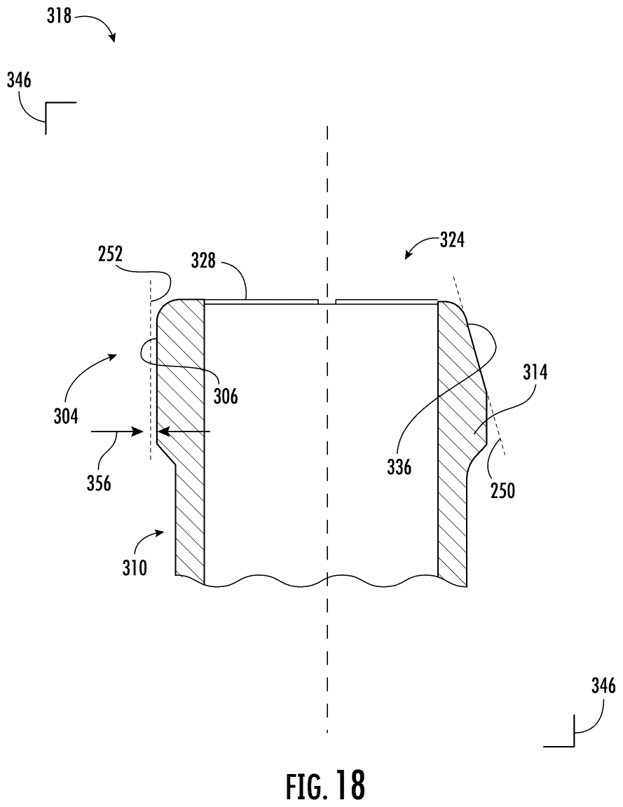

With reference to FIGS. 15-18, the actuator tube member 300 is shown according to an example of the disclosure. Referring to FIG. 15, the actuator tube member 300 is configured and adapted to seat thereon the lift pin actuator 200 (shown in FIG. 1) and in this respect includes a tube member body 308. It is contemplated that the tube member body 308 be arranged along the rotation axis 174 and extend about the rotation axis 174. It is also contemplated that the tube member body 308 have an actuation end 310 coupled to the seat end 304 by an intermediate segment 312, and that the tube member body 308 be formed from a ceramic material 314 (shown in FIG. 18). In certain examples, the ceramic material 314 may be transparent to electromagnetic radiation within an infrared waveband. Examples of suitable ceramic materials include fused silica, quartz, and sapphire. In accordance with certain examples, the ceramic material 314 may consist of or consist essentially of the ceramic material 314.

The actuation end 310 of the tube member body 308 is configured for engagement to an actuation device, for example the lift and rotate module 150 (shown in FIG. 3), and in this respect may define therein a through-hole or longitudinal slot 316. The intermediate segment 312 of the tube member body 308 extends axially from the actuation end 310 of the tube member body 308 and couples the seat end 304 of the tube member body 308 to the actuation end 310 of the tube member body 308. It is contemplated that seat end 304 of the tube member body 308 extends from the intermediate segment 312 to an end face 318, is separated from the actuation end 310 of the tube member body 308 by the intermediate segment 312 of the tube member body 308, and is configured to seat the lift pin actuator 200 (shown in FIG. 1).

It is contemplated that the tube member body 308 define a through-bore 320 (shown in FIG. 18) therethrough. The through-bore 320 couples an actuation end aperture 324 defined within an actuation end face 322 on the actuation end 310 to an end face aperture 326 (shown in FIG. 18) defined within the end face 318 on the seat end 304 of the tube member body 308. The through-bore 320 extends continuously and without interruption through the tube member body 308 along the rotation axis 174 and is sized and dimensioned to receive therethrough the shaft member 148 (shown in FIG. 3). In this respect it is contemplated that shaft member 148, when received within the through-bore 320, be separated from the interior surface 302 of the tube member body 308 by a radial gap 328. The radial gap 328 extends circumferentially about the shaft member 148 and axially between the actuation end aperture 324 and the end face aperture 326. As will be appreciated by those of skill in the art in view of the present disclosure, the shaft member 148 is thereby free to rotate about the rotation axis 174 relative to the actuator tube member 300 and the chamber body 130 to rotate the substrate support 142 (shown in FIG. 3) during processing of the substrate 2 (shown in FIG. 3). As will also be appreciated by those of skill in the art in view of the present disclosure, the actuator tube member 300 is thereby also free to translate axially along the rotation axis 174 relative to the shaft member 148 and the chamber body 130 to drive the lift pin actuator 200 between the retracted position 180 (shown in FIG. 5) and the extended position 182 (shown in FIG. 5) to seat and unseat the substrate 2 from the substrate support 142 before and after processing, respectively.

The intermediate segment 312 of the tube member body 308 extends between the actuation end 310 and the seat end 304 of the tube member body 308. In certain examples on the present disclosure the intermediate segment 312 may define an intermediate section diameter 330. The intermediate section diameter 330 may extend continuously and without interruption (span) the intermediate segment 312 of the tube member body 308. It is contemplated that the actuation end 310 of the tube member body 308 may have an actuator end diameter 332. The actuator end diameter 332 may be greater than the intermediate section diameter 330. It is also contemplated that the seat end 304 of the tube member body 308 may define a seat end diameter 334 that is greater than the intermediate section diameter 330. Advantageous, thickening either (or both) the seat end 304 and the actuation end 310 can strengthen the actuator tube member 300, facilitating installation and removal of the actuator tube member 300 from the semiconductor processing system 100 (shown in FIG. 1).

Referring to FIG. 16, the seat end 304 of the tube member body 308 is configured to seat thereon the lift pin actuator 200 and in this respect has a plurality of planar facets 336 defined on exterior surface 338 of the tube member body 308. It is contemplated that the plurality of planar facets 336 correspond to the plurality of planar faces 250 (shown in FIG. 13) defined by the interior surface 244 (shown in FIG. 13) of the hub portion 208 (shown in FIG. 13) of the lift pin actuator 200 (shown in FIG. 1). In this respect the plurality of planar facets 336 are distributed circumferentially about the rotation axis 174, are equal in number to the plurality of planar faces 250, and circumferentially spaced about the rotation axis 174 at an angular pitch matching that of the plurality of planar faces 250. In further respect, the plurality of planar facets 336 are further angled relative to the rotation axis 174, each of the plurality of planar facets 336 separated at greater distances from the rotation axis 174 at ends proximate the intermediate segment 312 of the tube member body 308 than at ends proximate the actuation end face 322.

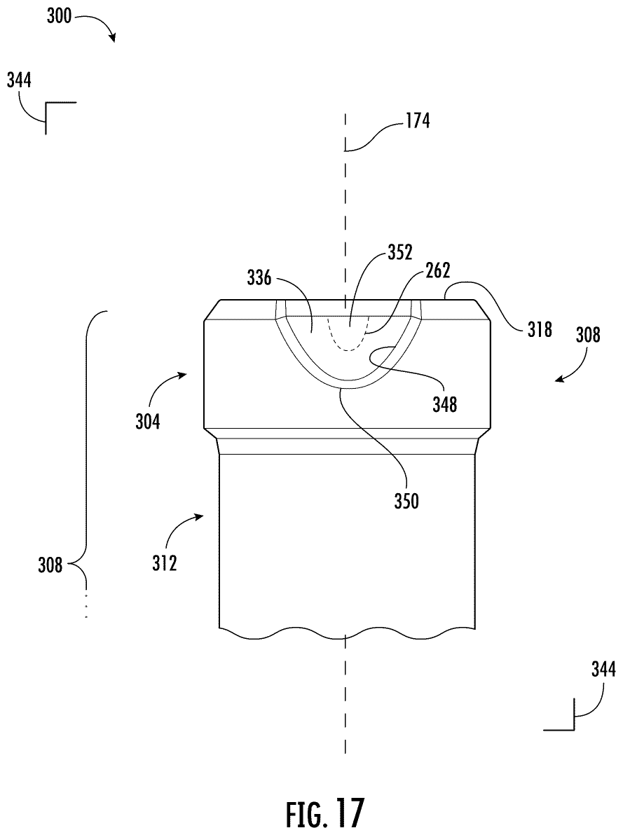

It is contemplated that the plurality of planar facets 336 each be angled relative to the rotation axis 174 (and/or relative to at least one of the actuation end 310 and the exterior surface 338 of the tube member body 308) at a common planar facet angle 340 (shown in FIG. 9). In certain examples, the common planar facet angle 340 may be an oblique angle. In accordance with certain examples, the common planar facet angle 340 may between about 5 degrees and 45 degrees, or between about 5 degrees and about 30 degrees, or between about 5 degrees and about 15 degrees, or even between about 5 degrees and about 10 degrees. It is contemplated that the common planar facet angle 340 match (e.g., be substantially equivalent) to the common planar face angle 254 (shown in FIG. 9). Advantageously, matching the common planar facet angle 340 to the common planar face angle 254 enables locating the lift pin actuator 200 (shown in FIG. 1) on the actuator tube member 300 using a 3-2-1 locating method. Locating the lift pin actuator 200 on the actuator tube member 300 in turns enables constraining the lift pin actuator 200 in six degrees of freedom relative to actuator tube member 300 using gravity as a clamping force. In this this respect it is contemplated that the lift pin actuator 200 be constrained relative to the actuator tube member 300 in translation and rotation within first plane 342 (shown FIG. 16), a second plane 344 (shown in FIG. 17), and a third plane 346 (shown in FIG. 18), limiting (or eliminating) the tendency of the lift pin actuator 200 to pitch or roll due to unequal loads exerted by the plurality of lift pins 144 (shown in FIG. 3) during movement from the retracted position 180 (shown in FIG. 5) to the extended position 182 (shown in FIG. 5).

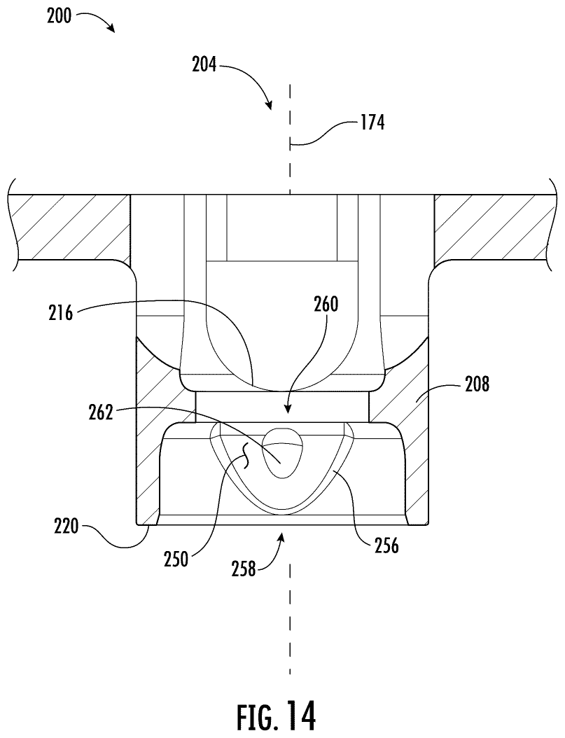

Referring to FIG. 17, it is contemplated that one or more of the plurality of planar facet 336 may be bounded by an arcuate edge 348. The arcuate edge 348 may extend from a base 350, proximate the intermediate segment 312 of the tube member body 308, and an open end 352 proximate the end face 318. In certain examples, the arcuate edge 348 of the one or more plurality of planar facets 33 may correspond (e.g., match) the arcuate periphery 256 (shown in FIG. 14) of the lift pin actuator 200 (shown in FIG. 1). In accordance with certain examples, the plurality of planar facets 336 may each have a planar area greater than a planar area of each of the plurality of planar faces 250 defined by the interior surface 244 (shown in FIG. 13) of the hub portion 208 (shown in FIG. 10) of the lift pin actuator 200. Advantageously, this enables locating the lift pin actuator 200 on the actuator tube member 300 using the 3-2-1 locating method at contact points circumferentially spaced about the rotation axis 174, for example at contact points circumferentially separated from one another by the relief channel 262 (shown in FIG. 14). As will be appreciated by those of skill in the art in view of the present disclosure, although shown and described herein as defined within the planar faces 250 (shown in FIG. 14), it is to be understood and appreciated that relief channels may alternatively (or additionally) be defined within one or more the plurality of planar facets 336 and remain within the scope of the present disclosure.

With continuing reference to FIGS. 13 and 16 as well as with reference to FIG. 18, it is contemplated that the exterior surface 338 of the tube member body 308 define the plurality of arcuate facets 306. The plurality of arcuate facets 306 are distributed circumferentially about the rotation axis 174, separate circumferentially adjacent planar facets 336, and circumferentially separated from one another by individual one of the plurality of planar facets 336. It is contemplated that the plurality of arcuate facets 306 be substantially parallel to the rotation axis 174 and are overcut relative to corresponding and radially overlapping one of the plurality of arcuate faces 252 defined by the interior surface 244 (shown in FIG. 14) of the hub portion 208 (shown in FIG. 10) of the actuator body 204. As shown in FIG. 13, it is further contemplated that (a) each of the planar faces 250 within the lift pin actuator 200 radially overlap a respective one of the plurality of planar facets defined by the seat end 304 of the actuator tube member 300, (b) each of the plurality of arcuate faces 252 defined within the lift pin actuator 200 radially overlap a respective one of the plurality of arcuate facets 354 defined by the seat end 304 of the actuator tube member 300, and (c) each of the plurality of planar faces 250 defined within the lift pin actuator 200 abuts respective one of the plurality planar facets 336 defined by the seat end 304 of the actuator tube member 300. Notably, the overcut provides a clearance 356 between radially overlapping ones of the plurality of arcuate faces 252 defined with the hub portion 208 and ones of the plurality of the arcuate facets 306 defined by the actuator tube member 300. The clearance 356 in turn causes the lift pin actuator 200 to locate on the plurality of planar facets 336 at the plurality of planar faces 250, promoting stability (e.g., resist pitch and roll) of the lift pin actuator 200 on the actuator tube member 300.

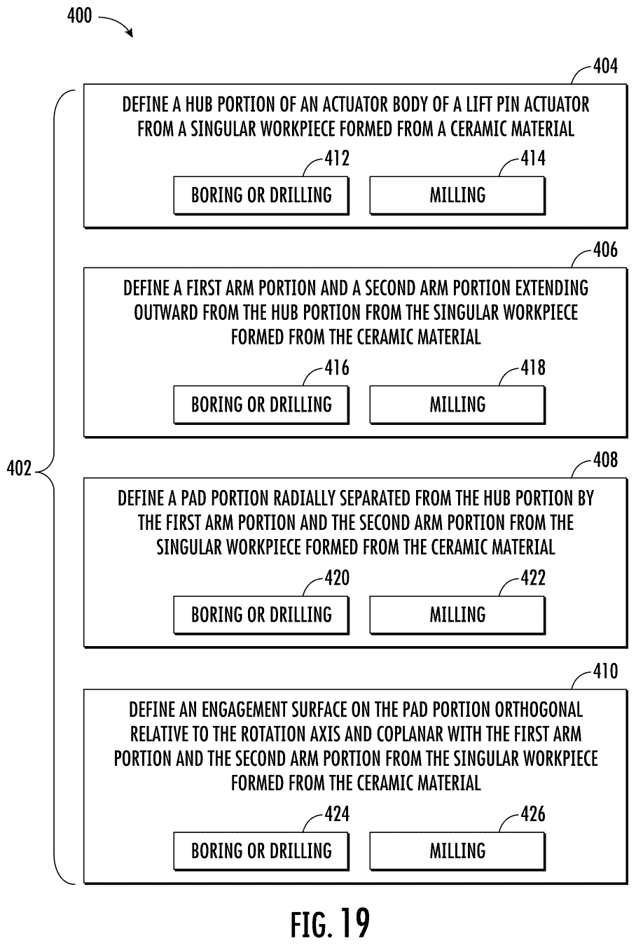

With reference to FIG. 19, a method 400 of making a lift pin actuator, e.g., the lift pin actuator 200 (shown in FIG. 1), is shown. The method 400 includes forming a lift pin actuator body e.g., the actuator body 204 (shown in FIG. 10), from a singular workpiece body, e.g., the singular workpiece 26 (shown in FIG. 12), formed from a ceramic material, e.g., the ceramic material 206 (shown in FIG. 5), as shown with bracket 402. Forming 402 the lift pin actuator body includes defining a hub portion of the lift pin actuator body from the singular workpiece, e.g., the hub portion 208 (shown in FIG. 10), as shown with box 404. Forming 402 the lift pin actuator body also includes defining a first arm portion and a second arm portion of the lift pin actuator body from the singular workpiece, e.g., the first arm portion 210 (shown FIG. 10) and the second arm portion 212 (shown in FIG. 10), as shown with box 406. Forming 402 the lift pin actuator body further includes defining a pad portion of the lift pin actuator body from the singular workpiece, e.g., the pad portion 214 (shown in FIG. 10), as shown with box 408. It is contemplated that forming 402 the lift pin actuator body additionally include defining an engagement surface on the pad portion of the lift pin actuator body from the singular workpiece, e.g., the engagement surface 230 (shown in FIG. 12), as shown with box 410.

It is contemplated that one or more of the defining operations 504-410 include forming a portion and/or engagement surface of the lift pin actuator body using two or more subtractive manufacturing techniques. In this respect the hub portion may be formed using a boring or drilling operation and a milling operation, as shown with box 412 and box 414. In further respect, the first arm portion and the second arm portion of the actuator body may be formed using a boring or drilling operation and a milling operation, as shown with box 416 and box 418. It is also contemplated that the pad portion of the actuator body may be formed using a drilling or boring and a milling operation, as shown with box 420 and box 422, and that the engagement surface may additionally be formed on the pad portion using a boring or drilling operation and a milling operation, as shown with box 424 and box 426. As will be appreciated by those of skill in the art in view of the present disclosure, forming the actuator body using subtractive manufacturing techniques may limit (or eliminate entirely) the need to weld the actuator body, limiting associated distortion and improving yield of the process used to fabricate the lift pin actuator. As will also be appreciated by those of skill in the art in view of the present disclosure, forming the actuator body using a boring or drill operation and a milling operation can reduce time required for fabrication of the actuator body due to the relatively high material removal rates associated with boring or drilling in relation to milling ceramic materials, limiting cost of the lift pin actuator.

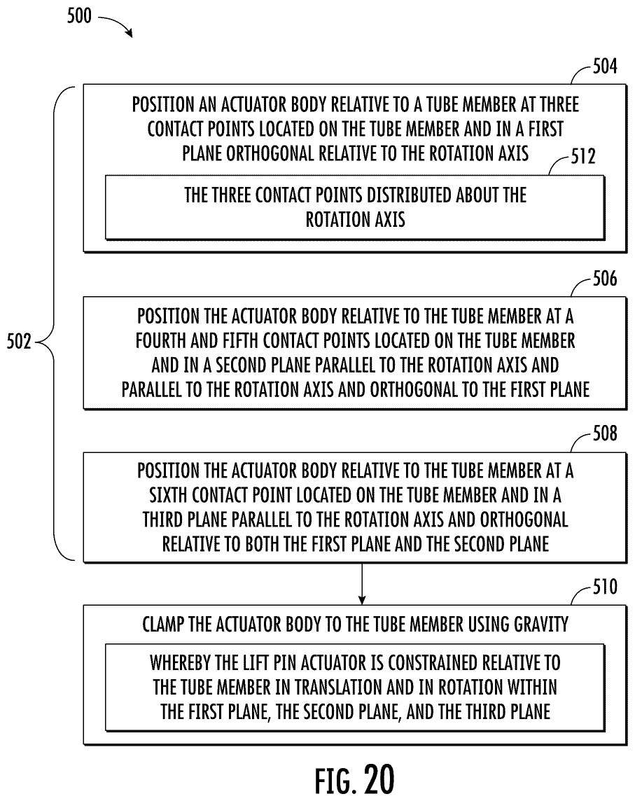

With reference to FIG. 20, a method 500 of making an actuator arrangement, e.g., the actuator arrangement 110 (shown in FIG. 3), is shown. The method 500 incudes positioning a lift pin actuator on an actuator tube member according to a 3-2-1 locating method to locate the lift pin actuator on the actuator tube member, e.g., positioning the lift pin actuator 200 (shown in FIG. 1) on the actuator tube member 300 (shown in FIG. 1), as shown with bracket 502. In this respect it is contemplated that positioning 502 the lift pin actuator include positioning the lift pin actuator relative to the actuator tube member include positioning the lift pin actuator at three (3) contact points located one the actuator tube member in a first plane orthogonal relative to the rotation axis 174, e.g., three (3) of the contact points identified using the 3-2-1 locating method (shown in FIG. 16) in the first plane 342 (shown in FIG. 16), as shown with box 504 and box 512. In further respect, it is also contemplated that positioning 502 the lift pin actuator relative to the actuator tube member include positioning the lift pin actuator relative to the tube member body at a fourth and a fifth contact points located in second plane parallel to the rotation axis and orthogonal to the first plane, e.g., two of the six contact points of the 3-2-1 position (shown in FIG. 16) the second plane 344 (shown in FIG. 17), as shown with box 506.

It is further contemplated that positioning 502 the lift pin actuator relative to the actuator tube member include positioning the lift pin actuator at a six contact point located in a third plane parallel to the rotation axis and orthogonal relative to the first plane and the second plane, e.g., a sixth of the six contact points identified using the 3-2-1 locating method (shown in FIG. 16) lying in the third plane 346 (shown in FIG. 18), as shown with box 508. Positioned according to the 3-2-1 locating method, the lift pin actuator is clamped to the actuator tube member using gravity such that the lift pin actuator is constrained relative to the actuator tube member in translation and in rotation within the first plane, the second plane, and the third plane, as shown with box 510. Advantageously, constrained, movement (e.g., roll and pitch) of the lift pin actuator relative to the actuator tube member during operation is limited (or absent entirely), enabling the pad portions of the lift pin actuator to relatively small. Small pad portions in turn limit shading of the substrate support by the lift pin actuator, improving temperature control of the substrate seated on the substrate support, and limiting cross-substrate variation otherwise induced in the material layer deposited onto the substrate due to cross-substrate temperature variation.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A lift pin actuator, comprising:
an actuator body arranged along a rotation axis having:
a hub portion extending about the rotation axis;
a first arm portion and a second arm portion extending outward from the hub portion and in a direction opposite the rotation axis, the second arm portion parallel to the first arm portion; and
a pad portion radially separated from the hub portion by the first arm portion and the second arm portion, the pad portion coupling the first arm portion to the second arm portion,
wherein the pad portion has an engagement surface that is orthogonal relative to the rotation axis and coplanar with the first arm portion and the second arm portion of the actuator body and configured to drive a lift pin above the engagement surface of the pad portion of the actuator body along the rotation axis.

2. The lift pin actuator of claim 1, wherein the pad portion is one of three (3) pad portions distributed circumferentially about the hub portion of the actuator body.

3. The lift pin actuator of claim 1, wherein the first arm portion and the second arm portion form a first arm pair of the actuator body, and wherein the actuator body has three (3) arm pairs distributed circumferentially about the hub portion of the actuator body.

4. The lift pin actuator of claim 1, wherein the actuator body is formed from a ceramic material, and wherein the actuator body is monolithically formed from a singular ceramic workpiece using a subtractive manufacturing technique.

5. The lift pin actuator of claim 1, wherein the hub portion has an upper surface defining an upper surface aperture therein, a lower surface defining a seating aperture therein, and an interior surface coupling the upper surface aperture to the seating aperture.

6. The lift pin actuator of claim 5, wherein the interior surface of the hub portion defines a plurality of planar faces distributed circumferentially about the rotation axis.

7. The lift pin actuator of claim 6, wherein the plurality of planar faces are angled relative to at least one of the upper surface and the lower surface at a planar surface angle that is between about 5 degrees and about 45 degrees.

8. The lift pin actuator of claim 6, wherein the interior surface of the hub portion defines a plurality of arcuate faces distributed circumferentially about the rotation axis, wherein the plurality of arcuate faces are substantially parallel to the rotation axis.

9. The lift pin actuator of claim 6, wherein one or more of the plurality of planar faces is bounded by an arcuate periphery having a base proximate the lower surface of the hub portion and an open end proximate the upper aperture of the hub portion, and wherein the one or more of the plurality of planar faces defining a relief channel therein extending from the open end to a location intermediate the open end and the base of the arcuate periphery.

10. The lift pin actuator of claim 1, wherein the hub portion of the actuator body has an annular segment and a plurality of merlon segments, wherein the plurality of merlon segments extend axially from the annular segment, and wherein the plurality of merlon segments axially separate the first arm portion and the second arm portion from the annular segment of the hub portion.

11. An actuator arrangement, comprising:
a lift pin actuator as recited in claim 1;
an actuator tube member arranged along the rotation axis, wherein the lift pin actuator is seated on the actuator tube member;
wherein the actuator tube member has an exterior surface defining a plurality of planar facets distributed circumferentially about the rotation axis;
wherein the lift pin actuator has an interior surface with a plurality of planar faces distributed circumferentially about the rotation axis; and
wherein each of the plurality of planar faces defined by the interior surface of the actuator member abuts a respective one of the plurality of planar facets defined by the exterior surface of the actuator tube member to locate the lift pin actuator on the actuator tube member.

12. The actuator arrangement of claim 11, wherein the exterior surface of the actuator tube member defines three (3) planar facets, wherein the interior surface of the lift pin actuator defines three (3) planar faces, and wherein each of the planar faces radially overlaps a respective one of the plurality of planar facets.

13. The actuator arrangement of claim 11, wherein the plurality of planar facets are angled relative to the rotation axis at a planar facet angle that is between about 5 degrees and about 45 degrees, and wherein the plurality of planar faces are angled relative to the rotation axis at a planar face angle substantially equivalent to the planar facet angle.

14. The actuator arrangement of claim 11, wherein the exterior surface of the actuator tube member defines a plurality a plurality of arcuate facets, wherein the interior surface of the lift pin actuator defines a plurality of arcuate faces, and wherein each of the plurality arcuate faces radially overlaps a respective one of the plurality of arcuate facets.

15. The actuator arrangement of claim 14, wherein each of the plurality of arcuate faces defined by the interior surface of the lift pin actuator are radially offset from a respective one of the plurality of arcuate facets defined by the exterior surface of the actuator tube member.

16. The actuator arrangement of claim 14, wherein the exterior surface of the actuator tube member defines three (3) arcuate facets distributed circumferentially about the rotation axis, and wherein the interior surface of the lift pin actuator defines three (3) arcuate faces distributed circumferentially about the rotation axis.

17. The actuator arrangement of claim 11, further comprising a shaft member arranged within the actuator tube member and supported for rotation about the rotation axis, wherein the plurality of planar facets and the plurality of planar faces radially overlap the shaft member.

18. A semiconductor processing system, comprising:
a chamber body;
a lift pin actuator as recited in claim 1 arranged within the chamber body;
an actuator tube member extending through a lower wall of the chamber body, the lift pin actuator seated on the actuator tube member;
a shaft member arranged within the actuator tube member and supported for rotation about the rotation axis; and
a substrate support seated on the shaft member with a plurality of lift pins slidably received therein,
wherein the lift pin actuator is arranged axially between the lower wall of the chamber body and the plurality of lift pins and configured to seat and unseat substrates from the substrate support.

19. A method of making a lift pin actuator, comprising:
forming a lift pin actuator body from a singular workpiece body formed from a ceramic material using a boring or drilling operation and a milling operation by:
defining a hub portion extending about a rotation axis;
defining a first arm portion and a second arm portion extending outward from the hub portion and in a direction opposite the rotation axis, the second arm portion parallel to the first arm portion;
defining a pad portion radially separated from the hub portion by the first arm portion and the second arm portion coupling the first arm portion to the second arm portion; and
defining an engagement surface of the pad portion orthogonal relative to the rotation axis and coplanar with the first arm portion and the second arm portion of the actuator body,
whereby the engagement surface of the pad portion of the actuator body is configured to drive a lift pin above the engagement surface of the pad portion along the rotation axis.

20. A method of making an actuator arrangement, comprising:
at a lift pin actuator including an actuator body arranged along a rotation axis and having a hub portion extending about the rotation axis; a first arm portion and a second arm portion extending outward from the hub portion and in a direction opposite the rotation axis, the second arm portion parallel to the first arm portion; a pad portion radially separated from the hub portion by the first arm portion and the second arm portion, the pad portion coupling the first arm portion to the second arm portion, the pad portion having an engagement surface that is orthogonal relative to the rotation axis and coplanar with the first arm portion and the second arm portion of the actuator body and configured to drive a lift pin above the engagement surface of the pad portion of the actuator body along the rotation axis;
positioning the actuator body relative to the actuator tube member at three contact points located on the actuator tube member and in a first plane orthogonal relative to the rotation axis, the three contact points distributed about the rotation axis;
positioning the actuator body relative to the actuator tube member at a fourth and a fifth contact points located on the actuator tube member and in a second plane parallel to the rotation axis and parallel to the rotation axis and orthogonal to the first plane;
positioning the actuator body relative to the actuator tube member at a sixth contact point located on the actuator tube member and in a third plane parallel to the rotation axis and orthogonal relative to both the first plane and the second plane; and
clamping the actuator body to the actuator tube member using gravity, whereby the lift pin actuator is constrained relative to the actuator tube member in translation and in rotation within the first plane, the second plane, and the third plane.
